(19) United States
(12) Patent Application Publication
(10) Pub. No.: US 2006/0283627 A1
(43) Pub. Date: Dec. 21, 2006

(54) Substrate structure of integrated embedded passive components and method for fabricating the same

(75) Inventors: Ying-Chou Chen, Tainan City (TW); Ying-Te Ou, Kaohsiung City (TW); Chiu-Wen Lee, Tainan City (TW)

Correspondence Address: Genus Law Group PLLC;Raymond J. Ho; David B. Dort, Box 26219, Crystal City Station, Arlington, VA, 22215, US

(73) Assignee: ADVANCED SEMINCONDUCTOR ENGINEERING, INC., Kaohsiung (TW)

(21) Appl. No.: 11/302,165

(22) Filed: Dec. 14, 2005

(30) Foreign Application Priority Data
Jun. 17, 2005 (TW) 94120260

(51) Int. Cl. H05K 1/16; H05K 3/30

(52) U.S. Cl. 174/260; 174/250; 29/832; 29/846

(57) ABSTRACT

The present invention is related to a substrate structure and a method for fabricating the substrate, and more particularly to a substrate structure of integrated embedded passive components and a method for fabricating the substrate. In the present invention, the openings are formed on the substrate by removing part of external circuit layer and part of dielectric layer. Then, the embedded components are disposed in these openings. Therefore, the shift and short circuit of the passive components caused by the flow and gather of the solder paste in reflow or other high-temperature processes can be improved.

### BACKGROUND OF THE INVENTION

1. Field of the Invention

The present invention generally relates to a substrate structure and a method for fabricating the substrate, more particularly to a substrate structure of integrated embedded passive components and a method for fabricating the substrate.

2. Description of the Prior Art

In semiconductor processes, the integrated circuits (ICs) manufactured on the same wafer are usually of the same types because to manufacture different types of ICs on the same wafer will increase its difficulty and complexity, and its cost is higher, and it is difficult to expand its functions, and it has the drawbacks of long development time and long test time, etc. However, in order to meet the requested functions of the electronic products and because their functions cannot be reached by only one IC or only the same types of ICs, it is necessary to integrate different types of components to complete the electronic products with whole functions. Nowadays, how to integrate different types of semiconductor components to be a low-cost, high-efficiency, and easy-manufacture electronic products is a development key to electronic packages.

Referring to FIG. 1A to FIG. 1C, a conventional electronic package of integrated passive components is illustrated. First, referring to FIG. 1A, a substrate 10 having a wiring layer for surface mount is provided. Several bonding pads 101 on the substrate 10 are electrically connected to the corresponding electrical wiring (not shown in the figure). The substrate 10 can be printed circuit board (PCB) or ceramic circuit board, etc. Next, a solder paste 12 is formed on the bonding pad 101, as shown in FIG. 1B. Then, as shown in FIG. 1C, by solder paste 12 the needed passive components 14 are mounted and fastened on bonding pads 101 of the substrate 10.

However, the electronic package method often needs at least one reflow process, which is high-temperature process. The reflow processes will cause the passive components shift due to the melted solder paste, and they will also cause that the passive components cannot be fixed on the bonding pads or misaligned to the locations of the bonding pads. It will cause some problems happen on the electronic circuits between the passive components and bonding pads. Furthermore, the melted solder paste on the adjacent bonding pads will flow and gather, and then will cause short circuit.

Therefore, how to prevent the electronic package of integrated components from short circuit and from damaging the products due to the flow and gather of melted solder paste after several reflow processes is a very important subject.

### SUMMARY OF THE INVENTION

In terms of the aforementioned difficulties, an object of the present invention is to provide a substrate structure of integrated embedded passive components to prevent the components from shift and short circuit due to the flow and gather of the melted solder paste after several high-temperature reflow processes. It will further reduce the failures of products, and will increase the yield of the products.

Another object of the present invention is to provide a method for fabricating a substrate of integrated embedded passive components. After several reflow processes, the components can be still firmly disposed on the bonding pads of the substrate without shift, and can be free from open circuit or disconnection. It will further improve the quality of the products and increase the yield of the products.

In order to achieve the above-mentioned objects, the present invention provides a substrate structure of integrated embedded passive components. The substrate structure includes a core board and an inner wiring layer formed on the core board. A dielectric layer is formed to cover the inner wiring layer and at least one opening is formed to expose part of the inner wiring layer. Then, an outer wiring layer is formed on top of the dielectric layer. Besides, at least one embedded component having at least one connecting point is disposed inside the opening and electrically connected to the exposed inner wiring layer.

The present invention further provides a method for fabricating a substrate of integrated embedded passive components. First, a substrate having a core board, an inner wiring layer on top of the substrate, a dielectric layer on the inner wiring layer and an outer wiring layer on the dielectric layer is provided. Next, part of the outer wiring layer and part of the dielectric layer are removed to form an opening. The opening exposes part of the inner wiring layer. An embedded component is disposed inside the opening, and electrically connected to the exposed inner wiring layer.

According to the present invention, the substrate structure of integrated embedded components and a method for fabricating the substrate are provided. Insulating plastic material surrounds the embedded components. Then, it can effectively fix the embedded components and prevent the embedded components from shift and short circuit due to the flow and gather of the melted solder paste after several reflow processes. It can improve the quality of the products, and increase the yield of the products.

### BRIEF DESCRIPTION OF THE DRAWINGS

FIG. 1A to FIG. 1C show the cross-sectional diagrams of a conventional method for fabricating integrated embedded components.

FIG. 2 is a cross-sectional diagram of a substrate structure of integrated embedded components according to one embodiment of the present invention.

FIG. 3A to FIG. 3E show the cross-sectional diagrams of a method for fabricating a substrate of integrated embedded components according to another embodiment of the present invention.

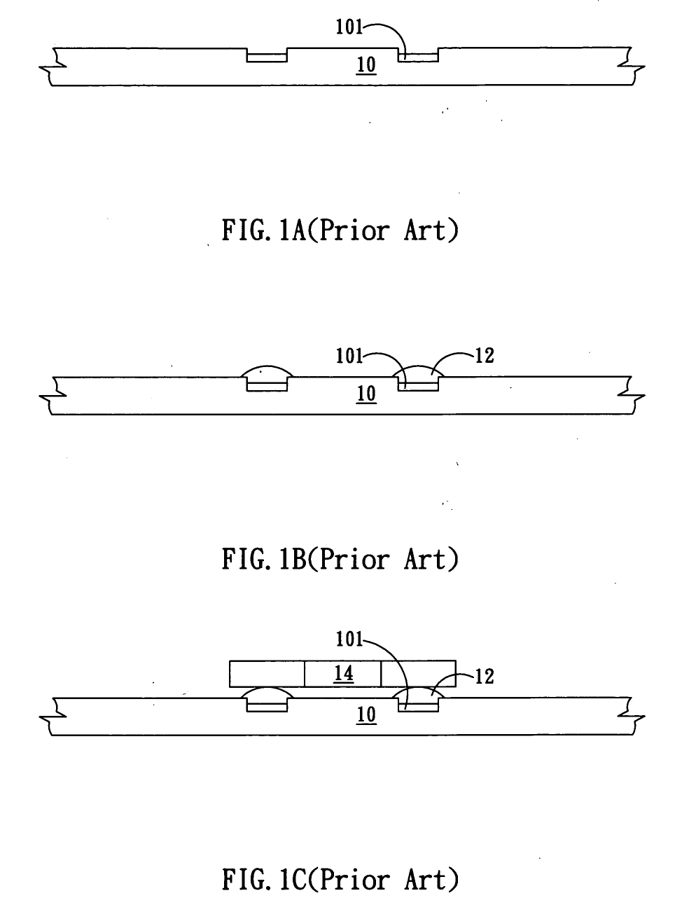

### DETAILED DESCRIPTION OF THE INVENTION

The detailed description of the present invention will be discussed in the following embodiments, which are not intended to limit the scope of the present invention, but can be adapted for other applications. While drawings are illustrated in details, it is appreciated that the quantity of the disclosed components may be greater or less than that disclosed, except expressly restricting the amount of the components.

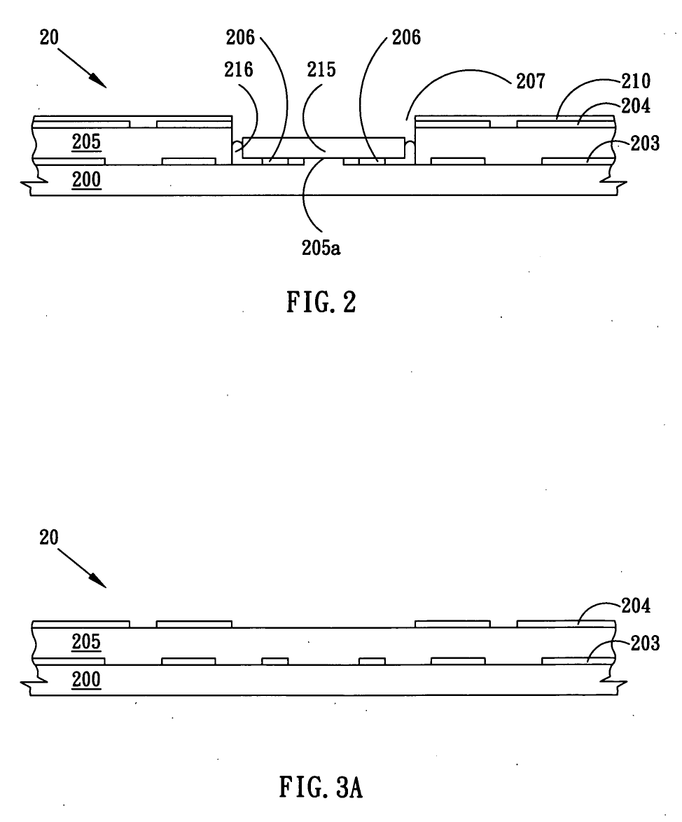

FIG. 2 shows a cross-sectional diagram of a substrate structure of integrated embedded components according to a preferred embodiment of the present invention. A substrate 20 of integrated components includes a core board 200, on which an inner wiring layer 203 with designed pattern is formed. A dielectric layer 205 is formed on the inner wiring layer 203 to protect the inner wiring layer 203, and an opening 207 in the dielectric layer 205 exposes part of the inner wiring layer 206. Furthermore, an outer wiring layer 204 is formed on the dielectric layer 205. An embedded device 215 having at least one connecting point is disposed inside the opening 207, and electrically connected to the inner wiring layer 206. Furthermore, a solder mask 210 is deposited to cover the outer wiring layer 204 to protect the outer wiring layer 204. There are several vias (not shown in the figure) between the outer wiring layer 204 and the inner wiring layer 203, and the vias electrically interconnects the outer wiring layer 204 and the inner wiring layer 203 to from a circuit.

Furthermore, the exposed inner wiring layer 206 in the opening 207 is separately paired wirings, which are respectively connected to the connecting points of the embedded component 215 by solder paste (not shown in the figure). The embedded component 215 is a passive component, but not limited to this scope. There is a protruding 205a at the bottom of the opening 207 between the separately paired wirings 206, and the protruding 205a not only isolates the separately paired wirings 206 but also isolates the solder paste used to electrically interconnect the separately paired wirings 206 and the embedded component 215. It prevents the component from short circuit due to the flow and gather of the melted solder paste after several high-temperature processes, such as reflow process. The embedded component 215 disposed confined inside the opening 207 has limited surrounding. Furthermore, the surrounding of the embedded component 215 is filled with an insulating plastic material 216. Therefore, even during reflow process, the embedded component 215 will not shift and expose the inner wiring layer 206 as conventional technology, and will be fixed even though the solder paste is melted by the high-temperature processes.

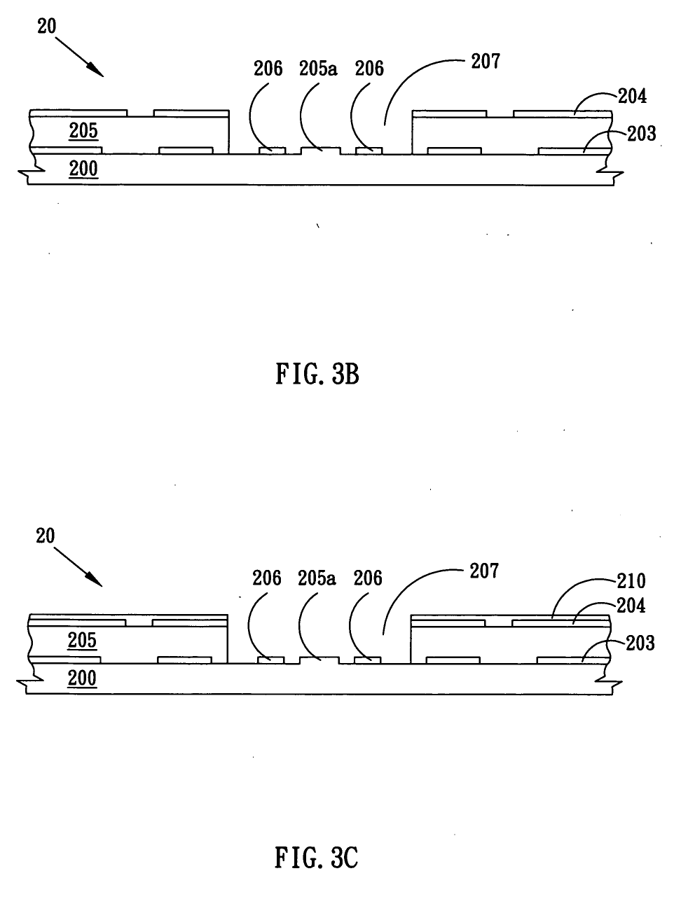

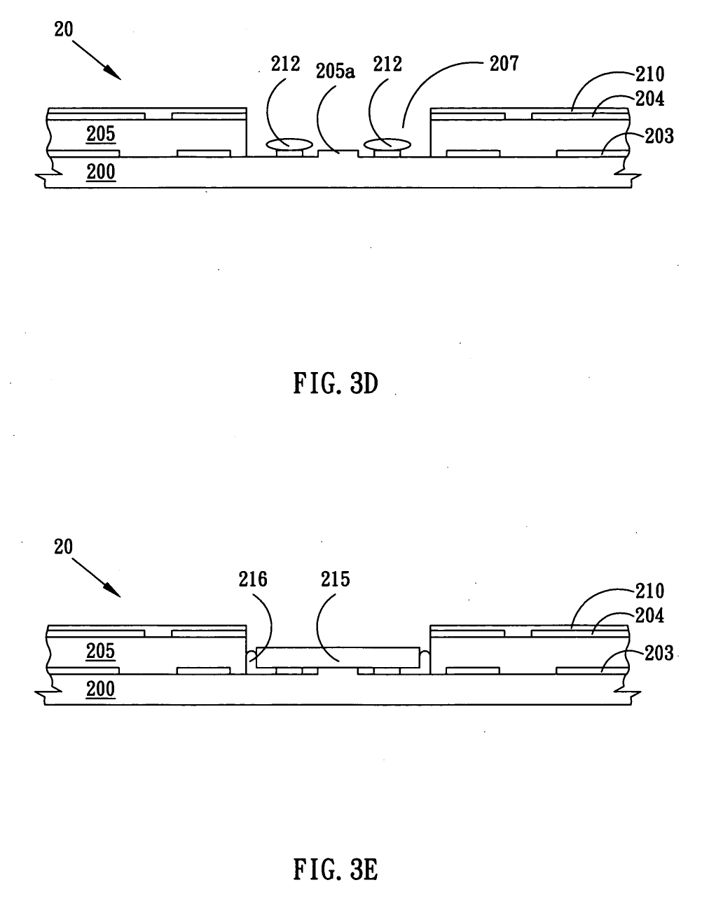

FIG. 3A to FIG. 3E show the cross-sectional diagrams of a substrate structure of integrated embedded components according to another embodiment of the present invention. First, a substrate 20 is provided, as shown in FIG. 3A. The substrate 20 is fabricated by forming an inner wiring layer 203 on a core board 200, and a dielectric layer 205 is deposited on the inner wiring layer 203, and an outer wiring layer 204 is formed on the dielectric layer 205. Next, as shown in FIG. 3B, part of the outer wiring layer 204 and part of the dielectric layer 205 are removed to form an opening 207, and part of the inner wiring layer 206 is exposed, but part of the dielectric layer remained at the bottom of the opening 207 is kept to form a protruding 205a. However, the exposed inner wiring layers 206 are separately paired wirings, and the protruding 205a is located between the exposed inner wiring layers 206, and isolates the separately paired wirings. The method for forming the opening 207 is by conventional technology such as etching method, etc.

Furthermore, as shown in FIG. 3C, a solder mask 210 is formed on the outer wiring layer 204 to protect the outer wiring layer 204. Next, a flux 212 or a solder paste dipped on the exposed inner wiring layer 206 is used as a surface mount material, as shown in FIG. 3D. Then, as shown in FIG. 3E, an embedded component 215 disposed inside the opening 207 is connected to the exposed inner wiring layer 206 and fixed on it by the previous dipped flux 212. The space inside the opening 207 and surrounding the embedded component 215 is filled with an insulating plastic material 216 to make sure the embedded component 215 firmly fixed inside the opening 207. Then, after a reflow process the substrate of integrated embedded substrate is fabricated.

The opening of the present invention is used to dispose passive component, and the flux and the insulating plastic material can effectively fasten the embedded component 215, so that after reflow or other high-temperature processes the passive component will not shift as conventional technology due to the flow or gather of the melted solder paste. The protruding formed by the remained dielectric inside the opening isolates the exposed inner wiring layer inside the opening, so that it can prevent the component from short circuit due to the flow and gather of the melted solder paste after reflow or other high-temperature process. Therefore, it will improve the yield of the products.

Although specific embodiments have been illustrated and described, it will be appreciated by those skilled in the art that various modifications may be made without departing from the scope of the present invention, which is intended to be limited solely by the appended claims.

What is claimed is:

1. A substrate structure of integrated embedded components, comprising:
a core board;
an inner wiring layer on said core board;
a dielectric layer to cover said inner wiring layer and said dielectric layer having at least one opening to expose part of said inner wiring layer;
at least one embedded component having at least one connecting point electrically connected to said exposed inner wiring layer; and
an outer wiring layer on said dielectric layer.

2. The substrate structure of integrated embedded components according to claim 1, further comprising forming a solder mask on said outer wiring layer.

3. The substrate structure of integrated embedded components according to claim 1, wherein said embedded components are passive components.

4. The substrate structure of integrated embedded components according to claim 1, further comprising a plurality of vias to electrically interconnect said inner wiring layer and said outer wiring layer.

5. The substrate structure of integrated embedded components according to claim 1, further comprising an insulating plastic material surrounding said embedded components.

6. The substrate structure of integrated embedded components according to claim 1, further comprising an insulating layer formed on sidewalls of said opening.

7. The substrate structure of integrated embedded components according to claim 1, wherein said exposed inner wiring layers are separately paired wirings at the bottom of said opening.

8. The substrate structure of integrated embedded components according to claim 7, further comprising a protruding formed between said separately paired wirings at the bottom of said opening to isolate said paired wirings.

9. A method for fabricating substrate of integrated embedded passive components, comprising the steps of:
providing a substrate having a core board, an inner wiring layer on said core board, a dielectric layer to cover said inner wiring layer, and an outer wiring layer on said dielectric layer;
removing part of said outer wiring layer and part of dielectric layer to form at least one opening and to expose part of said inner wiring layer; and
disposing each of said embedded components inside each of said openings and electrically connecting said embedded component and said exposed inner wiring layer, wherein said embedded component is disposed inside said opening.

10. The method for fabricating substrate of integrated embedded passive components according to claim 9, further comprising filling an insulating plastic material inside said at least one opening and said insulating plastic material surrounding said embedded components.

11. The method for fabricating substrate of integrated embedded passive components according to claim 9, wherein steps of disposing said embedded component comprises dipping a flux on said exposed inner wiring layer and reflowing said embedded component.

12. The method for fabricating substrate of integrated embedded passive components according to claim 9, wherein part of said outer wiring layer and part of said dielectric layer are removed to form said openings, and part of said dielectric layer is remained between said adjacent exposed inner wiring layers.
